(19) United States
(12) Patent Application Publication
(10) Pub. No.: US 2004/0070954 A1
(43) Pub. Date: Apr. 15, 2004

(54) Tower housing of network device

(75) Inventor: Shu-Chu Fan, Hsinchu (TW)

Correspondence Address: BACON & THOMAS, PLLC, 625 SLATERS LANE, FOURTH FLOOR, ALEXANDRIA, VA, 22314

(73) Assignee: D-LINK CORPORATION, Hsinchu (TW)

(21) Appl. No.: 10/267,594

(22) Filed: Oct. 10, 2002

(51) Int. Cl. H05K 5/00; H05K 5/04; H05K 5/06

(52) U.S. Cl. 361/752

(57) ABSTRACT

The present invention is to provide a tower housing of a network device comprising a plurality of slots on two opposite sides and two opposite edges at both an underside and a top and a plurality of pads each having two opposite ridges inserted into the slots for fastening. This can increase a stability of the housing on a supporting surface.

### FIELD OF THE INVENTION

The present invention relates to network devices and more particularly to a tower housing of such network device with improved characteristics.

### BACKGROUND OF THE INVENTION

A commercially available network product (e.g., modem) is shown in FIG. 1. The network product comprises a parallelepiped housing 1 comprises two elongate first sides 11, two short second sides 12, and two thrid sides 10 including a top and an underside. In general, either top or underside is rested on a supporting surface for obtaining an improved stability of the housing 1. However, such orientation may occupy a considerable area on a user's desk. In other words, available space for installing other equipment on the user's desk is reduced significantly. In an alternate orientation of the housing 1, either second side 12 is rested on the supporting surface for saving space. However, it is disadvantageous for being lack of stability due to higher height and smaller base area. In a typical case a person may accidentally collide the housing 1 to cause it to fall. As a result, interior components of the network device may be damaged or even hurt someone unintentionally.

Referring to FIG. 1 again, there is provided at least one circuit board in the housing 1. The circuit board has a variety of electronic components mounted thereon. The electronic components are enabled to generate signals for communication in a normal operation. Heat generated by the electronic components in the housing is transferred to a surface of the housing 1 prior to dissipating to air by convection. This can prevent too much heat from being accumulated in the housing 1. Otherwise, the network device may be damaged or down due to overheat. In one case one advantage of utilizing the top or underside of housing 1 as a base rested on the supporting surface is an increase of stability of the housing 1. However, such also has a disadvantage, i.e., poor ventilation as the base is proximate the supporting surface resulting in a lowering of heat dissipation rate, in the other case one advantage of utilizing the second side of housing 1 as a base rested on the supporting surface is an increase of heat dissipation rate. However, it also has a disadvantage, i.e., unstable as the second side has a less area. In a worse case, the unstable housing 1 is subject to fall when a person accidentally collides the housing 1.

Thus, it is desirable to provide a housing of network device having a less occupied area on the supporting surface, an increased heat dissipation rate, and a reduced manufacturing cost in order to overcome the above drawbacks of the prior art.

### SUMMARY OF THE INVENTION

It is an object of the present invention to provide a tower housing of a network device. The housing comprises a plurality of slots on two opposite sides and two opposite edges at both an underside and a top and a plurality of pads each having two opposite ridges inserted into the slots for fastening. This can increase a stability of the housing on a supporting surface. By utilizing this, a number of conventional drawbacks such as lowering of heat dissipation rate and waste of limited space on a supporting surface are eliminated.

### BRIEF DESCRIPTION OF THE DRAWINGS

FIG. 1 is a perspective view of a conventional network device;

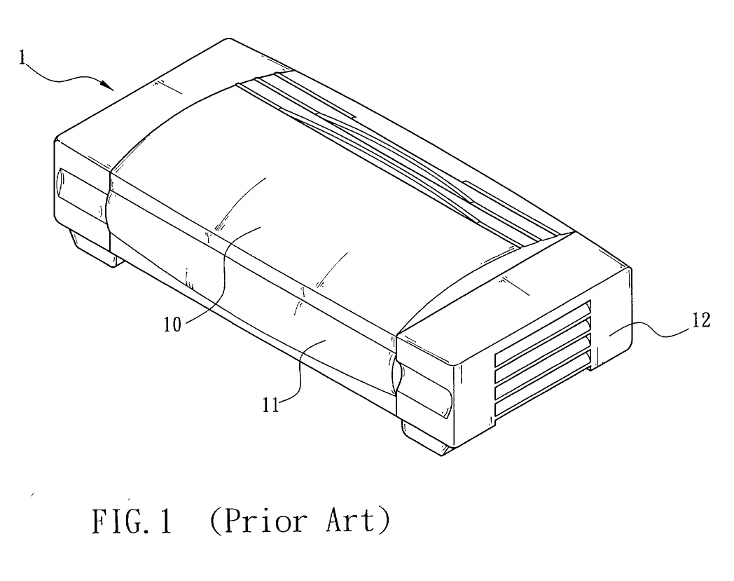

FIG. 2 is a perspective view of a network device having a tower housing according to the invention;

FIG. 3 is a perspective view of pad shown in FIG. 2;

FIG. 4 is a cross-sectional view showing the fastening of housing onto housing of the network device; and

FIG. 5 is a perspective view showing a connection of two network devices and an electronic device.

### DETAILED DESCRIPTION OF THE PREFERRED EMBODIMENTS

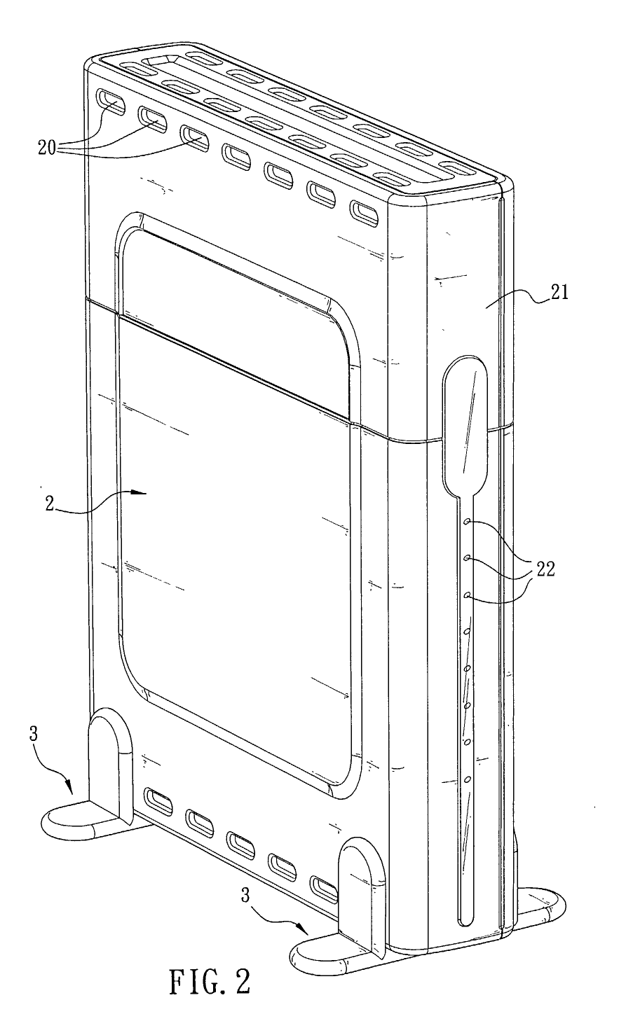

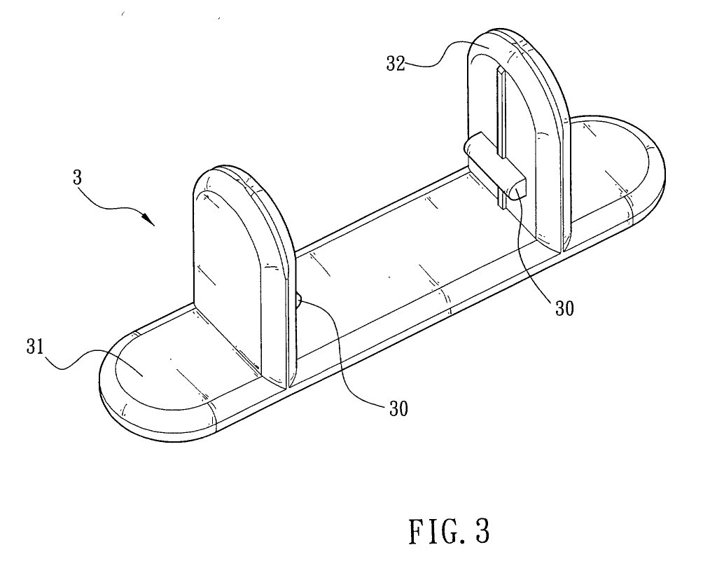

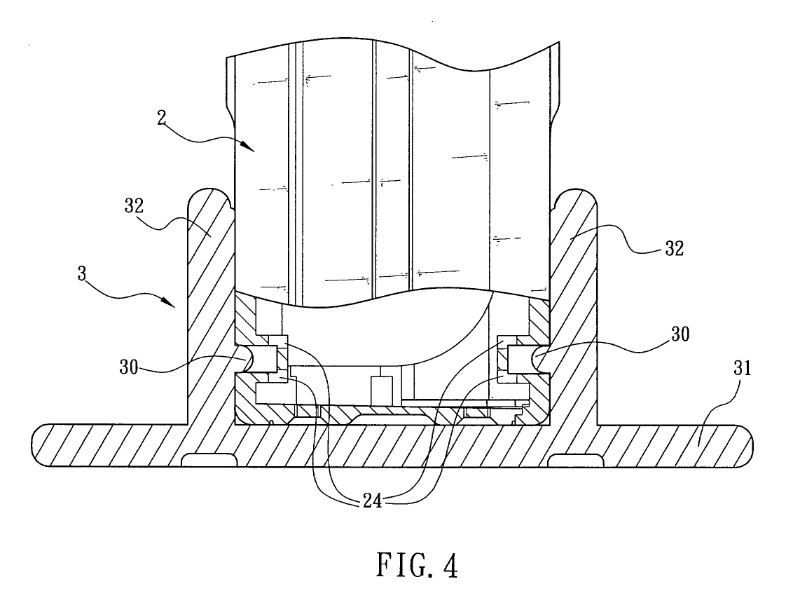

Referring to FIGS. 2, 3, and 4, there is shown a network device having a tower housing 2 constructed in accordance with the invention. The tower housing 2 is a parallelepiped and comprises a plurality of slots 20 on both an underside and a top and two opposite edges at two opposite sides and at least one pad 3 (two are shown in FIG. 2) each fastened to two slots 20 near the underside of the housing 2. Thus, the housing 2 is rested on a supporting surface (e.g., desk) by means of the pads 3. That is, the pads are served as a base for reliably supporting the housing 2 on the supporting surface. Such configuration has the benefits of saving space on the supporting surface and an increase of heat dissipation rate.

Referring to FIGS. 2, 3 and 4 again, the pad 3 comprises a flat base 31 and two spaced uprights 32 extended from the base 31 for forming a space therebetween. As shown, either end of the underside of the housing 2 is sandwiched and fastened by two uprights 32. One upright 32 comprises at least one ridge 30 (one is shown) facing the ridge 30 of the other upright 32. The ridges 30 are provided for an increase of fastening of the pad 3 in the slots 20 or removing the same from the slots 20. In detail, the ridges 30 are urged against inside of the slots 20 after the pad 3 has been inserted into the slots 20. Also, preferably the pad 3 is formed of a flexible material for ease of the fastening of the ridges 30 in the slots 20 or a disengagement therebetween.

Referring to FIGS. 2, 3 and 4 again, as stated above, the number of the pad 3 is at least one. In a case that one pad 3 is provided an area of the base 31 may be relatively small. This has the undesired effect of instability of the housing 2. For overcoming such disadvantage, the area of the base 31 can be suitably designed to have one of different values. With such configuration, even in the case of only one pad 3 being provided, the housing 2 still can be stably supported on the supporting surface. Note that the slots 20 at one side of the housing 2 are arranged parallel adjacent edges of the housing 2 in a pairing relationship.

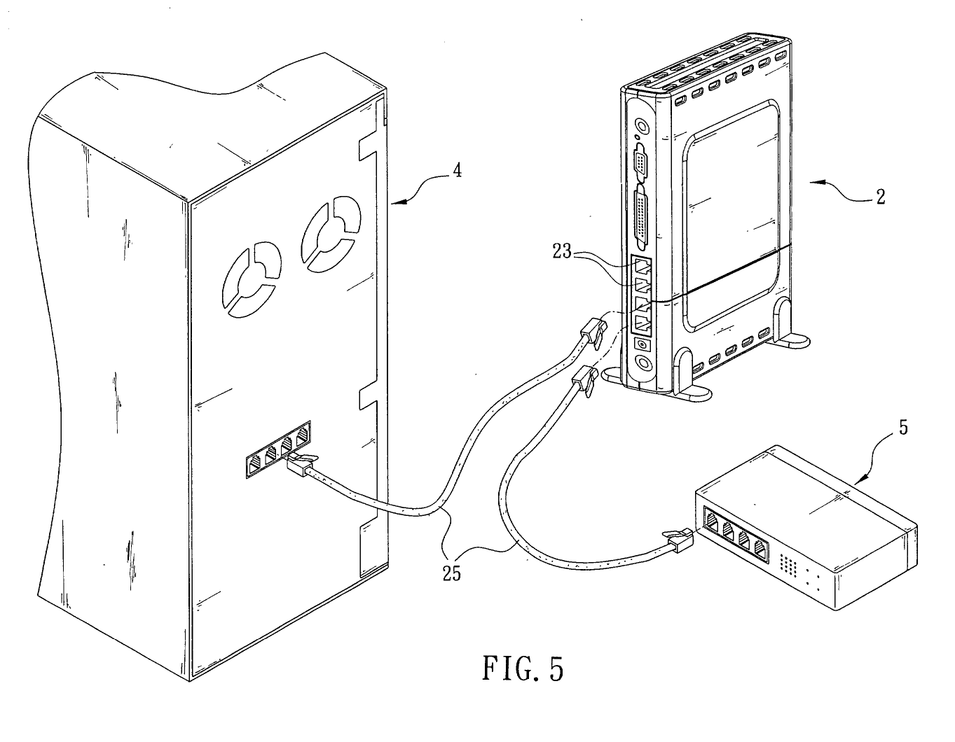

Referring to FIGS. 2, 3, 4, and 5, in the invention there is provided at least one circuit board in the housing 2. The circuit board has a variety of electronic components mounted thereon. The electronic components are enabled to generate signals for connecting to a network (e.g., the Internet) in a normal operation. In addition, a display panel 21 and a plurality of ports 23 are formed on a side of the tower housing 2 without the provision of the slots 20. The display panel 21 comprises a plurality of light emitting elements 22 electrically coupled to the circuit board. Thus, a user can understand the status of an operating network device by observing the light emitting elements 22. A cable 25 for signal communication is interconnected between one port 23 on the housing 2 of the network device and an electronic device 4. Also, another cable 25 is interconnected between the other port 23 and a second network device 5. As such, the electronic device 4 and the second network device 5 are coupled together for signal communication and processing.

However, it is also found that a rate of the heat dissipation by convection from surface is too slow. Further, there is a possibility that the electronic components in the housing 2 may be damaged in such undesired heat dissipation environment. Hence, in the invention an opening 24 is provided in either an inner wall having the provision of the slots 20 distal from one side of the housing 2 or at a junction of the bottom and the inner wall of the slots 20. Hence, only several ones of the slots 20 on the housing 2 are coupled to the pads 3. This can maintain a stable seating of the housing 2 on the supporting surface. As to the opening 24 in the other slots 20 on the housing 2 disconnected from the pad 3 is open to the outside so that heat generated in the housing 2 can be transferred to air. Moreover, a position at an edge of the opening 24 coupled to the bottom of the slots 20 is perpendicular to the side of the slots 20. Thus, spark generated by the malfunctioned electronic components in the housing 2 cannot fall out of the housing 2 from the opening 24.

What is claimed is:

1. A structure of a network device comprising:
a parallelepiped housing for enclosing the network device;
a plurality of slots on both an underside and a top and two opposite edges at two opposite sides; and
a plurality of pads each fastened to two slots proximate the underside of the housing.

2. The structure of claim 1, wherein the pad comprises:
a flat base;
two spaced uprights extended from the base for forming a space therebetween with either end of the underside of the housing being sandwiched and fastened by a pair of the uprights; and
two ridges each formed on one of the uprights facing the other ridge of the other upright, the ridges being urged against inside of the slots after the pad has been inserted into the slots proximate the underside of the housing.

3. The structure of claim 1, wherein the housing comprises at least one interior circuit board having a variety of electronic components mounted thereon, the electronic components being enabled to generate signals for connecting to a network.

4. The structure of claim 1, wherein the housing further comprises a display panel and a plurality of ports formed on a side of the housing without the provision of the slots, the display panel having a plurality of light emitting elements electrically coupled to the circuit board so that it is possible of understanding a status of the network device being in operation by observing the light emitting elements, and the ports being connectable to a cable for signal communication with either a second network device or an electronic device.

5. The structure of claim 1, wherein the housing further comprises an opening in an inner wall having the provision of the slots distal from a side of the housing so that in response to a coupling of a first portion of the slots on the housing to the pads and a disconnection of a second remaining portion of the slots on the housing from the pads, the housing is in communication with outside.

6. The structure of claim 1, wherein the housing further comprises an opening at a junction of a bottom and the inner wall of the slots so that in response to a coupling of a first portion of the slots on the housing to the pads and a disconnection of a second remaining portion of the slots on the housing from the pads, the housing is in communication with outside.

7. The structure of claim 1, wherein each of the pads is formed of a flexible material.

8. The structure of claim 1, wherein the slots at one side of the housing are arranged parallel adjacent edges of the housing in a pairing relationship.
